(19) United States
(12) Patent Application Publication
(10) Pub. No.: US 2008/0135900 A1
(43) Pub. Date: Jun. 12, 2008

(54) METHOD OF FORMING ORGANIC FERROELECTRIC FILM, METHOD OF MANUFACTURING MEMORY ELEMENT, MEMORY DEVICE, AND ELECTRONIC APPARATUS

(75) Inventors: Hiroshi TAKIGUCHI, Suwa-shi (JP); Junichi KARASAWA, Shimosuwa-machi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/937,197

(22) Filed: Nov. 8, 2007

(30) Foreign Application Priority Data
Nov. 13, 2006 (JP) 2006-307153
Nov. 7, 2007 (JP) 2007-290164

(51) Int. Cl. H01L 27/115; H01L 21/00

(52) U.S. Cl. 257/295; 438/3; 257/E27.104

(57) ABSTRACT

A method of forming an organic ferroelectric film configured to include an organic ferroelectric material with a crystalline property as a principal material includes (a) forming a low crystallinity film having a crystallinity lower than a crystallinity of the organic ferroelectric film on one surface of a substrate, and (b) forming the organic ferroelectric film from the low crystallinity film. The step (a) includes applying a liquid material containing the organic ferroelectric material on the one surface of the substrate and then drying the liquid material, and the step (b) includes heating and pressurizing the low crystallinity film to enhancing the crystallinity in the low crystallinity film while fairing the low crystallinity film.

### BACKGROUND OF THE INVENTION

1. Technical Field

The present invention relates to a method of forming an organic ferroelectric film, a method of manufacturing a memory element, a memory device, and an electronic apparatus.

2. Related Art

As a memory element, there is known an element which data is written to and retrieved from by applying an electric field to a ferroelectric film made of a ferroelectric material in the thickness direction thereof to vary the polarization state. Such a memory element has a bistable polarization state in the ferroelectric film, which is held after application of the electric field has been stopped, and consequently, can be used as a nonvolatile memory.

In recent years, with a goal of making such a memory element flexible and so on, it has been proposed to use an organic ferroelectric material as the ferroelectric material. As such an organic ferroelectric material, with a view to improving the memory characteristics and so on, there is used the organic ferroelectric material having a crystalline property disclosed in Japanese Journal of Applied Physics, Vol. 89, No. 5, pp. 2613-16.

In forming the ferroelectric film using such an organic ferroelectric material, a process using a liquid containing an organic ferroelectric material and combining a liquid phase thin film forming process such as a spin coat method and a crystallization process is more suitable than a vapor phase thin film forming process such as an evaporation method having difficulty in controlling the crystalline property on the front of freedom of material selection and process cost.

For example, in the past, such a liquid has been applied on a lower electrode, then dried and crystallized to form a ferroelectric film, and then an upper electrode has been formed on the ferroelectric film using a vapor phase film forming method. Since it is possible to form the ferroelectric film using such a liquid without using such large vacuum equipment as required in a vapor phase thin film forming process under a condition nearly at normal temperature and normal pressure, energy saving and cost reduction in manufacturing the memory element can be provided.

However, in the past, since the liquid applied on the lower electrode has been dried and crystallized in an exposed condition, unevenness caused by coarse crystal grains has been formed on the surface of the ferroelectric film on the side opposite to the lower electrode while crystallization of the organic ferroelectric material has proceeded. Therefore, in the past manufacturing method of the memory element, if the thickness of the ferroelectric film becomes as thin as nearly the size of the crystal grains, the electrode material enters concave portions of the unevenness of the ferroelectric film in forming the upper electrode, thus the distance between the upper electrode and the lower electrode is locally decreased to make a too close condition or a contact condition, which might cause increase in the leakage current or short between the upper electrode and the lower electrode. Since the unevenness of the ferroelectric film as described above is not substantially varied if the thickness of the ferroelectric film varies, the smaller the thickness of the ferroelectric film becomes, the more remarkable the harmful influence is becomes.

The organic ferroelectric material represented by a copolymer of vinylidene fluoride and trifluoroethylene, or a polymer of vinylidene fluoride generally has very high coercive field, and consequently, it is required to make the film thickness of the ferroelectric thin film extremely small in order for achieving low voltage drive. However, due to the circumstances described above, for the present, it has been very difficult to achieve the low voltage drive of the memory element by making the thickness of the ferroelectric film extremely small.

### SUMMARY

An advantage of the present invention is to provide a method of forming an organic ferroelectric film, a method of manufacturing a memory element, a memory device, and an electronic apparatus.

The advantage described above is obtained by the present invention described below.

According to an aspect of the invention, there is provided a method of forming an organic ferroelectric film configured to include an organic ferroelectric material with a crystalline property as a principal material including the step of (a) forming a low crystallinity film having a crystallinity lower than a crystallinity of the organic ferroelectric film on one surface of a substrate, and the step of (b) forming the organic ferroelectric film from the low crystallinity film, wherein the step (a) includes the step of applying a liquid material containing the organic ferroelectric material on the one surface of the substrate and then drying the liquid material, and the step (b) includes the step of heating and pressurizing the low crystallinity film to enhancing the crystallinity in the low crystallinity film while fairing the low crystallinity film.

Further, in this aspect of the invention, the crystallinity in the low crystallinity film is preferably no higher than 80% of the crystallinity of the organic ferroelectric film.

Thus, the crystallization of the organic ferroelectric material proceeds while maintaining the condition in which the surface of the low crystallinity film on the side opposite to the substrate is smoothed by the tool. Therefore, it can be prevented that the crystal grains of the organic ferroelectric material grow freely to make the surface coarse. Therefore, the surface of the resulting organic ferroelectric film on the side opposite to the substrate is smoothed, thus the film thickness of the organic ferroelectric film from locally decreasing.

According to another aspect of the invention, there is provided a method of manufacturing an organic ferroelectric film configured to include an organic ferroelectric material with a crystalline property as a principal material including the step of (a) forming a low crystallinity film having a crystallinity lower than a crystallinity of the organic ferroelectric film on one surface of a substrate, and (b) forming the organic ferroelectric film from the low crystallinity film, wherein the step (a) includes the step of applying a liquid material containing the organic ferroelectric material on the one surface of the substrate and then drying the liquid material, and the step (b) includes the steps of (e) heating the low crystallinity film to form a crystalline film from the low crystallinity film enhanced in the crystallinity, and (f) heating and pressurizing the crystalline film to fair the crystalline film, thereby forming the organic ferroelectric film.

Thus, even if the coarseness caused by the crystal grains of the organic ferroelectric material is formed on the surface of the crystalline film on the side opposite to the substrate by the crystallization, the surface of the organic ferroelectric film on the side opposite to the substrate can be made smooth. Therefore, the film thickness of the organic ferroelectric film can be prevented from locally decreasing.

In this aspect of the invention, in the step (b), the pressure in the pressurizing step is preferably in a range of 0.1 through 10 MPa/cm².

Thus, the surface of the resulting organic ferroelectric film on the side opposite to the substrate can be made as an extremely smooth surface.

In this aspect of the invention, it is preferable that a thickness of the organic ferroelectric film is in a range of 5 through 500 nm.

Thus, the resulting organic ferroelectric film can be thinner, while further surely preventing the film thickness from locally decreasing.

In this aspect of the invention, it is preferable that the organic ferroelectric material is mainly composed of one of a copolymer of vinylidene fluoride and trifluoroethylene, a polymer of vinylidene fluoride, and a combination of the copolymer of vinylidene fluoride and trifluoroethylene and the polymer of vinylidene fluoride.

Such an organic ferroelectric material has a very high coercive field. Therefore, for example, the organic ferroelectric film including such an organic ferroelectric material as the composing material is used for the memory element, the organic ferroelectric film needs to have an extremely small thickness in order for achieving low drive voltage. Therefore, the advantage obtained by applying the embodiment of the invention becomes remarkable.

In this aspect of the invention, it is preferable that the liquid material containing the organic ferroelectric material is a solution dissolving the organic ferroelectric material with a solvent.

Thus, the resulting organic ferroelectric film can be thinner, while further surely preventing the film thickness from locally decreasing.

In this aspect of the invention, it is preferable that in the step (b), the temperature in the heating step for enhancing the crystallinity is in a range of 80 through 200° C.

Thus, the organic ferroelectric material in the low crystallinity film can effectively be crystallized.

In this aspect of the invention, it is preferable that the step (b) includes the step of performing cooling while maintaining the pressurized state after the crystallinity has been enhanced.

Thus, the surface of the organic ferroelectric film on the side opposite to the substrate can more surely be made to have the smoothed condition.

In this aspect of the invention, it is preferable that the cooling is performed at a temperature no higher than the glass-transition temperature of the organic ferroelectric material.

Thus, the crystallization can more surely be performed.

In this aspect of the invention, it is preferable that the step of (c) heating to soften the low crystallinity film is further included, wherein the step (c) is executed after the step (a) and prior to the step (b).

Thus, the surface of the organic ferroelectric film on the side opposite to the substrate can more surely be made to have the smoothed condition.

In this aspect of the invention, it is preferable that in the step (b), the fairing is executed by pressing a tool capable of defining an effective area of the organic ferroelectric film against the substrate.

Thus, the desired shape of the organic ferroelectric film can be obtained.

In this aspect of the invention, it is preferable that the tool is provided with a parting treatment on a pressing surface.

Thus, the removal of the tool becomes easy, and the organic ferroelectric material can be prevented from adhering to the tool, thereby making the smoothness of the surface of the organic ferroelectric film on the side opposite to the substrate more excellent.

In this aspect of the invention, it is preferable that in the step (b), in the pressurizing step, the crystallization is performed while applying an electric field between the tool and the first electrode.

Thus, the crystal orientations of the organic ferroelectric material in the resulting organic ferroelectric film can be aligned. Therefore, in the resulting memory element, the polarization loss caused by the directional fluctuation of the polarization axis can be reduced. In other words, since the polarization axis directions of the organic ferroelectric material in the resulting organic ferroelectric film can be aligned in a thickness direction (an application direction of the electric field) of the organic ferroelectric film as close as possible, in the resulting memory element, improvement of the response of polarization reversal can be achieved, and the squareness in the hysteresis curve can be made excellent.

According to another aspect of the invention, there is provided a method of manufacturing a memory element using an organic ferroelectric film configured to include an organic ferroelectric material with a crystalline property as a principal material, including the steps of (d) forming a first electrode on one surface of a substrate, (a) forming a low crystallinity film having a crystallinity lower than a crystallinity of the organic ferroelectric film on a surface of the first electrode on a side opposite to the substrate, (b) forming the organic ferroelectric film from the low crystallinity film, and (g) forming a second electrode on a surface of the organic ferroelectric film on a side opposite to the first electrode, wherein the step (a) includes the step of applying a liquid material containing the organic ferroelectric material on the one surface of the substrate and then drying the liquid material, and the step (b) includes the step of heating and pressurizing the low crystallinity film to enhancing the crystallinity in the low crystallinity film while fairing the low crystallinity film.

Thus, there can be provided a capacitor formed by mounting on the substrate a structure formed by holding the organic ferroelectric film between the first and second electrodes. In this case, since the surface of the organic ferroelectric film on the side opposite to the substrate is smoothed, the distance between the first and second electrodes can be prevented from locally decreasing. As a result, even if the organic ferroelectric film is made thinner, in the resulting memory element, the leakage current can be prevented from increasing, and at the same time, short circuit between the first and second electrodes can also be prevented. In other words, it becomes possible to reduce the thickness of the organic ferroelectric film to reduce the drive voltage.

Further, according to the invention, the memory element can be formed by a simple process in a relatively low temperature condition not requiring so much energy compared to vapor phase thin film forming process using large scale vacuum equipment. Therefore, the cost reduction of the manufacturing equipment can be achieved, and the range of choices for the material composing the memory element, consequently the memory device, is expanded.

In this aspect of the invention, the step of (h) forming a semiconductor film is further provided, wherein the step (h) is executed after the step (d) and prior to the step (a), the first electrode formed in the step (d) includes a pair of electrodes distant from each other, in the step (h), the semiconductor film is formed so as to have contact with each of the pair of electrode, and in the step (a), the low crystallinity film is formed on the surface of the semiconductor film on a side opposite to the substrate.

Thus, the memory element which can be used for the so-called 1T (transistor) memory device can be obtained. In this case, since the surface of the organic ferroelectric film on the side opposite to the substrate is smoothed, the distance between the semiconductor film and the second electrode can be prevented from locally decreasing. As a result, even if the organic ferroelectric film is made thinner, in the resulting memory element, the leakage current can be prevented from increasing, and at the same time, short circuit between the semiconductor film and the second electrode can also be prevented. In other words, it becomes possible to reduce the thickness of the organic ferroelectric film to reduce the drive voltage.

Further, according to the invention, the memory element can be formed by a simple process in a relatively low temperature condition not requiring so much energy compared to vapor phase thin film forming process using large scale vacuum equipment. Therefore, the cost reduction of the manufacturing equipment can be achieved, and the range of choices for the material composing the memory element, consequently the memory device, is expanded.

The memory device according to another aspect of the invention includes the memory element manufactured by the method of manufacturing a memory element according to the above aspect of the invention.

Thus, there can be provided a memory device capable of achieving the reduction of the drive voltage even if the organic ferroelectric material with a crystalline property is used as the composing material of the organic ferroelectric film. Further, such a memory device has a superior reliability because of the reduction of the leakage current and the prevention of the short circuit.

An electronic apparatus according to still another aspect of the invention includes the memory device according to the above aspect of the invention.

Thus, there can be provided an electronic apparatus capable of achieving the reduction of the drive voltage even if the organic ferroelectric material with a crystalline property is used as the composing material of the organic ferroelectric film. Further, such an electronic apparatus has a superior reliability because of the reduction of the leakage current and the prevention of the short circuit.

### BRIEF DESCRIPTION OF THE DRAWINGS

The invention will now be described with reference to the accompanying drawings, wherein like numbers refer to like elements.

FIG. 1 is a vertical cross-sectional view showing an embodiment of a memory element according to the invention.

FIGS. 2A through 2G are diagrams for explaining a first example of a manufacturing method of the memory element shown in FIG. 1.

FIGS. 3A through 3G are diagrams for explaining a second example of the manufacturing method of the memory element shown in FIG. 1.

FIG. 4 is a diagram schematically showing a circuit configuration of a memory device using the memory element 1 according to the embodiment of the invention.

FIGS. 5A and 5B are diagrams for explaining a fourth example of the manufacturing method of the memory element shown in FIG. 1.

FIGS. 6A through 6E are diagrams for explaining the manufacturing method of the memory element shown in FIGS. 5A and 5B.

FIG. 7 is a diagram schematically showing a fundamental circuit configuration of the memory device equipped with the memory element shown in FIGS. 6A through 6E.

FIGS. 8A through 8D are each a diagram for explaining a relationship between time and the temperature of a tool and a substrate, and a relationship between time and the pressure of the tool in the embodiments of the invention.

### DESCRIPTION OF THE EMBODIMENTS

Hereinafter, preferred embodiments of a manufacturing method, a memory element, a memory device, and an electronic apparatus according to the invention will be explained.

### First Embodiment

A first embodiment of the invention will be explained.

Memory Element

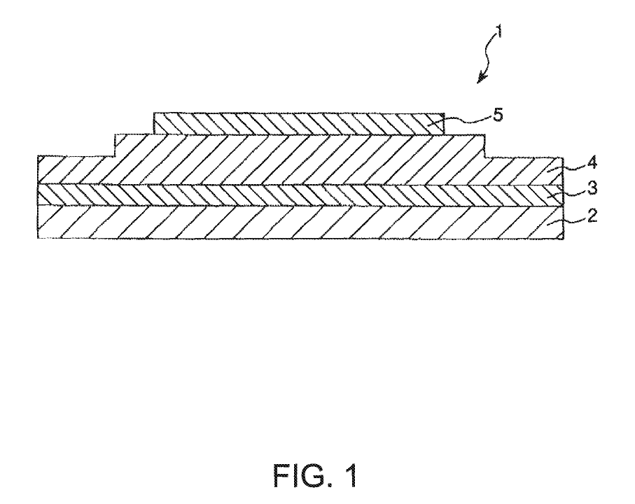

Firstly, an embodiment of a memory element manufactured using a manufacturing method of a memory element according to an embodiment of the invention, namely an embodiment of the memory element according to the invention will be explained with reference to FIG. 1.

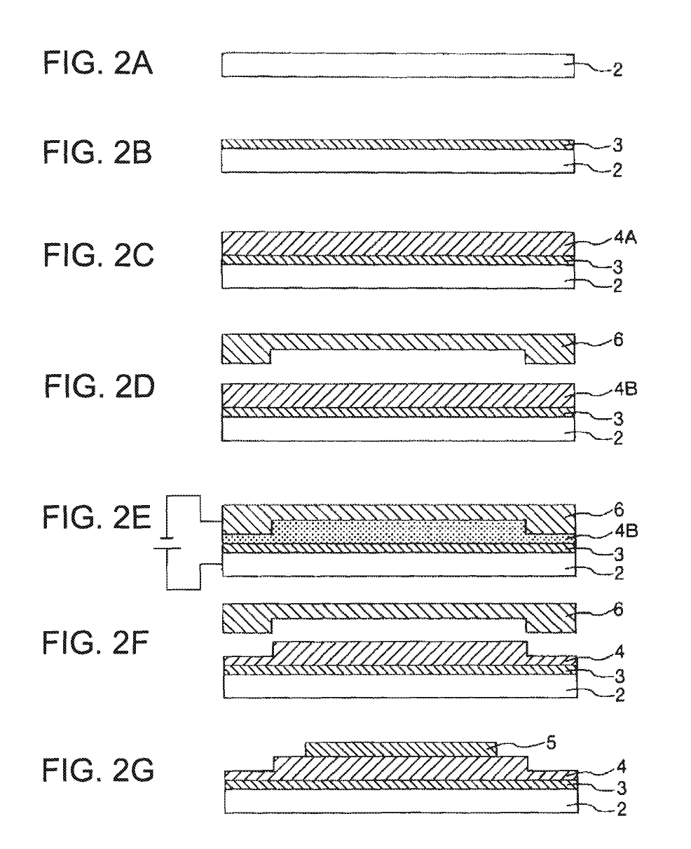

FIG. 1 is a vertical cross-sectional view showing a memory element according to the first embodiment of the invention. It should be noted that for the sake of explanatory convenience, “the upper side” and “the lower side” in FIGS. 2A through 2G are hereinafter referred to as “the upper side” and “the lower side.” respectively.

A memory element 1 shown in FIG. 1 is intended to be used while being implemented in various electronic devices such as a memory device, and is composed of a substrate 2, a lower electrode (a first electrode)3, an organic ferroelectric film 4, and an upper electrode (a second electrode)5 stacked sequentially in this order. In other words, in the memory element 1, a structure having the organic ferroelectric film (a recording film)4 intervening between the lower electrode 3 and the upper electrode 5 is supported by the substrate 2 on the side of the lower electrode 3.

In such a memory element 1, writing and reading of the data can be performed by applying voltage (an electric field) between the lower electrode 3 and the upper electrode 5, and further, even after the application of the electric field has been stopped, the polarization state is maintained. Using such a characteristic, the memory element 1 can be used for a memory device.

As the substrate 2, a plastic substrate (a resin substrate) made of polyimide, polyethylene terephthalate (PET), polyethylene naphthalate (PEN), polymethylmethacrylate (PMMA), polycarbonate (PC), polyethersulfone (PES), aromatic polyester (liquid crystal polymer), or the like, a grass substrate, a quartz substrate, a silicon substrate, a gallium arsenide substrate and so on, for example, can be used. If the memory element needs to be flexible, the resin substrate is selected as the substrate 2.

A foundation film can be provided on the substrate 2. The foundation film is provided for, for example, preventing ions from diffusing from the surface of the substrate 2, or for enhancing adhesiveness (joining property) between the lower electrode 3 and the substrate 2.

Further, depending on the usage and so on, the substrate 2 can be eliminated.

A material for composing the fundamental film is not particularly limited, but silicon oxide (SiO₂), silicon nitride (SiN), polyimide, polyamide, or a polymer cross-linked to be insolubilized, and so on can preferably be used therefore.

Further, the thickness of the substrate 2 is not particularly limited, but is preferably in a range of 10 through 2000 μm.

On the upper surface (one of the surfaces of the substrate 2) of the substrate 2, there is formed the lower electrode 3.

A composing material of the lower electrode 3 is not particularly limited as long as it has electrical conductivity, and electrically conductive materials such as Pd, Pt, Au, W, Ta, Mo, Al, Cr, Ti, Cu, and alloys including such metals, electrically conductive oxides such as ITO, FTO, ATO, and SnO₂, carbonaceous materials such as carbon black, carbon nano tube, and fullerene, electrically conductive polymeric materials such as polyacetylene, polypyrrole, polythiophene such as PEDOT (poly-ethylenedioxythiophene), polyaniline, poly(p-phenylene), polyfluorene, polycarbazole, polysilane, and derivatives of the above, for example, can be cited and used alone or in combination as the composing material thereof. Note that the electrically conductive polymeric materials mentioned above are usually used in a condition provided with conductivity by being doped with iron oxide, iodine, inorganic acid, organic acid, or a polymer such as polystyrene sulfonic acid. Among these materials, as the composing material of the lower electrode 3, those composed mainly of Al, Au, Cr, Ni, Cu, or Pt, or an alloy including any of these materials are preferably used. By using these metal materials, the lower electrode 3 can easily be formed at low cost using an electrolytic or electroless plating method. Further, the characteristic of the memory element 1 can be improved.

Further, the thickness of the lower electrode 3 is not particularly limited, but is preferably in a range of about 10 through 1000 nm, and is further preferably in a range of about 50 through 500 nm.

On the upper surface (the surface of the lower electrode 3 on the side opposite to the substrate 2) of the lower electrode 3, there is formed the organic ferroelectric film 4.

The organic ferroelectric film 4 is composed using the organic ferroelectric material having a crystalline property as a principal material.

As the ferroelectric material, for example, P(VDF/TrFE) (a copolymer of vinylidene fluoride and trifluoroethylene), PVDF (a polymer of vinylidene fluoride), and so on can preferably be used. Such an organic ferroelectric material has a very high coercive field. Therefore, for example, the organic ferroelectric film 4 including such an organic ferroelectric material as the composing material is used for the memory element 1, the organic ferroelectric film 4 needs to have an extremely small thickness in order for achieving low drive voltage. Therefore, the advantage obtained by applying the embodiment of the invention becomes remarkable.

Further, the thickness of the organic ferroelectric film 4 is not particularly limited, but is preferably in a range of about 5 through 500 nm, and is further preferably in a range of about 10 through 200 nm. Thus, various drive performance of the memory element 1 (consequently, various electronic devices such as the memory device) can preferably be exerted. Further, the unevenness on the surface of the organic ferroelectric film 4 caused by the crystal grains, causing the leakage current or the short circuit in the ferroelectric film 4 can be suppressed into a low level, as a result, the low voltage driving of the memory element 1 can be achieved.

On the upper surface (the surface of the organic ferroelectric film 4 on the side opposite to the lower electrode 3) of the organic ferroelectric film 4, there is formed the upper electrode 5.

As the composing material of the upper electrode 5, materials similar to the composing materials for the lower electrode 3 described above can be used.

Further, the thickness of the upper electrode 5 is not particularly limited, but is preferably in a range of about 10 through 100 nm, and is further preferably in a range of about 50 through 500 nm.

Manufacturing Method of Memory Element

Then, the manufacturing method of the memory element according to the invention will be explained using the manufacturing method of the memory element 1 as one example.

### First Example

Firstly, a first example of the manufacturing method of the memory element 1 will be explained with reference to FIGS. 2A through 2G.

The manufacturing method of the memory element 1 includes a step of forming the lower electrode 3 (step A), a step of applying a liquid material containing the organic ferroelectric material on the lower electrode 3, then drying the material to form a low crystallinity film (step (a)) (step B), a step of heating and pressurizing the low crystallinity film to form the organic ferroelectric film (step (b)) (step C), and a step of forming the upper electrode on the organic ferroelectric film (step D).

Hereinafter, each of the steps will sequentially be explained in detail.

Step A: Step of Forming the Lower Electrode 3

Firstly, as shown in FIG. 2A, a substrate 2 such as a semiconductor substrate, a glass substrate, or a resin substrate is prepared, and on the upper surface of the substrate 2, the lower electrode 3 is formed as shown in FIG. 2B.

In particular, by using the resin substrate as the substrate 2, the resulting memory element 1, and consequently the memory device, can be made flexible.

The method of forming the lower electrode 3 is not particularly limited, but it can be formed by a physical vapor deposition method (PVD method) such as a vacuum evaporation method, a sputtering method (low-temperature sputtering method), or an ion plating method, a chemical vapor deposition method (CVD method) such as a plasma CVD method, a thermal CVD method, or a laser CVD method, a wet plating method such as an electrolytic plating method, a dip plating method, or electroless plating method, a solution coating method such as a spin coat method, or a liquid source misted chemical deposition method (LSMCD method), or various printing methods such as a screen printing method or an inkjet method.

Step B: Step of Forming a Low Crystallinity Film (the Step (a))

Subsequently, as shown in FIG. 2C, a liquid material 4A containing the crystalline organic ferroelectric material is applied (forming a film of the liquid material 4A) on the lower electrode 3, and then dried to form the low crystallinity film (including an amorphous film) 4B as an intermediate product for forming the organic ferroelectric film 4 as shown in FIG. 2D.

The low crystallinity film 4B is formed using the organic ferroelectric material as the principal material with a lower crystallinity than a final crystallinity of the organic ferroelectric material in the organic ferroelectric film 4. Further, assuming that the final crystallinity of the organic ferroelectric material in the organic ferroelectric film 4 is 100%, the crystallinity of the organic ferroelectric material in the low crystallinity film 4B is preferably in a range of 0.001 through 80%, and further preferably no greater than 50%.

As the liquid material 4A, a liquid obtained by dissolving the crystalline organic ferroelectric material by a solvent or dispersing the crystalline organic ferroelectric material in a dispersion medium can be used.

In particular, the liquid material 4A is preferably a solution obtained by dissolving the organic ferroelectric material by a solvent. Thus, the coating process of the substrate 2 with the liquid material 4A can be easier, and the thickness of the low crystallinity film 4B can be made even with relative ease. As a result, the resulting organic ferroelectric film 4 can be thinner, while further surely preventing the film thickness from locally decreasing.

As the organic ferroelectric material in the liquid material 4A, the composing material of the organic ferroelectric film 4 can be used. In particular, as the organic ferroelectric material, one of the copolymer of vinylidene fluoride and trifluoroethylene and the polymer of vinylidene fluoride alone or a combination of the two polymers is preferably used. Further, in order for obtaining the ferroelectricity with extreme ease, the copolymer of vinylidene fluoride and trifluoroethylene is further preferably used.

It should be noted that the liquid material 4A can include other materials than the organic ferroelectric material and one of the solvent and the dispersion medium.

The solvent or the dispersion medium in the liquid material 4A is not particularly limited providing it can dissolve or disperse the organic ferroelectric material, and an inorganic solvent such as nitric acid, sulfuric acid, ammonia, hydrogen peroxide, water, carbon disulfide, carbon tetrachloride, or ethylene carbonate, various organic solvents including a ketones solvent such as methyl ethyl ketone (MEK), acetone, diethyl ketone, methyl isopropyl ketone (MIPrK), methyl isopentyl ketone (MIPeK), acetylacetone, or cyclohexanon, an alcohols solvent such as diethylcarbonate (DEC), methanol, ethanol, isopropanol, ethylene glycol, diethylene glycol (DEG), or glycerine, an ethers solvent such as diethyl ether, diisopropyl ether, 1,2-dimetoxy ethane (DME), 1,4-dioxane, tetrahydrofuran (THF), tetrahydropyran (THP), anisole, diethylene glycol dimethyl ether (diglyme), or diethylene glycol ethyl ether (carbitol), a Cellosolve™ solvent such as methyl cellosolve, ethyl cellosolve, or phenyl cellosolve, an aliphatic hydrocarbons solvent such as hexane, pentane, heptane, or cyclohexane, an aromatic hydrocarbons solvent such as toluene, xylene, or benzene, a heteroaromatic solvent such as pyridine, pyrazine, furan, pyrrole, thiophene, or methylpyrrolidone, an amide solvent such as N,N-dimethylformamide (DMF) or N,N-dimethylacetamide (DMA), a halogenated compound solvent such as dichloromethane, chloroform, or 1,2-dichloroethane, an esters solvent such as ethyl acetate, methyl acetate, or ethyl formate, a sulfur compound solvent such as dimethyl sulfoxide (DMSO) or sulfolane, a nitrile solvent such as acetonitrile, propionitrile, or acrylonitrile, an organic acids solvent such as formic acid, acetic acid, trichloroacetic acid, or trifluoroacetic acid, or a mixed solvent including the above compounds can be used.

In particular, in the case of using P(VDF/TrFE) as the organic ferroelectric material, any one of various organic solvents including methyl ethyl ketone:2-butanone (MEK), methyl isopropyl ketone:3-methyl-2-butanone (MIPrK), 2-pentanone, 3-pentanone, methyl isobutyl ketone:4-methyl-2-pentanone (MIBK), 2-hexanone, 2,4-dimethyl-3-pentanone, 4-heptanone, methyl isopentyl ketone:5-methyl-2-hexanone (MIPeK), 2-heptanone, 3-heptanone, cyclohexanone, and diethylcarbonate (DEC), or a mixed solvent of the above compounds can preferably be used as the solvent therefor.

Further, the rate of content of the organic ferroelectric material in the liquid material 4A to be applied is preferably in a range of 0.1 through 8.0% by weight, and further preferably in a range of 0.2 through 4.0% by weight. Thus, the coating process of the substrate 2 with the liquid material 4A can be easier, and the thickness of the low crystallinity film 4B can be made even with relative ease.

The coating method of the liquid material 4A is not particularly limited, but for example, a spin coat method, a liquid source misted chemical deposition method (LSMCD method), or an inkjet method can preferably be used therefor.

The drying method of the liquid material, namely the method of removing the solvent or the dispersion medium from the liquid is not particularly limited, but, for example, an external heat drying method by a hot plate or an oven, an internal heat drying method by microwave, a hot-air drying method, a radiant heat transmission drying method by infrared ray, or a vacuum evacuation method can be used therefor.

It should be noted that in the case in which the solution or the dispersion liquid of the liquid material 4A has a high volatility, and the residual solvent or the residual dispersion medium hardly exists in the applied film, the drying step can be eliminated.

In the case of using a heat process as the drying method of the liquid material 4A, the process temperature should be kept no higher than the optimal crystallization temperature of the organic ferroelectric material, and is preferably in a range of a room temperature through 140° C., and more preferably in a range of a room temperature through 100° C. in a specific example depending on the types of organic ferroelectric material and the solvent in use, the film thickness of the liquid material 4A, and so on.

Further, on this occasion, the process time is preferably in a range of 0.5 through 120 minutes, and further preferably in a range of 1 through 30 minutes depending on the organic ferroelectric material in use, the film thickness of the liquid material 4A, and so on.

Further, in the case of forming the low crystallinity film by applying the liquid material 4A, the coating process can be repeated more than once. Thus, a small pinhole defect or the like formed in the evaporation process of the solvent is filled with the liquid material, thus the pinhole defects of the low crystallinity film are decreased, as a result, the ferroelectric film with little leakage current and short circuit can be formed. Further, by alternately repeating the coating step and the drying step described above, the low crystallinity film with little pinhole defects can also be formed.

Step C: Step of Forming the Organic Ferroelectric Film 4

Subsequently, by heating and pressurizing the low crystallinity film 4B, the crystallinity of the low crystallinity film 4B is increased while fairing the low crystallinity film 4B to obtain the organic ferroelectric film 4. Specifically, after performing crystallization of the low crystallinity film 4B by heating the low crystallinity film 4B while pressing a tool 6 against the substrate 2 via the low crystallinity film 4B as shown in FIG. 2E, the tool 6 is removed to obtain the organic ferroelectric film 4 as shown in FIG. 2F.

The pressure with which the tool 6 is pressed against the substrate 2 is preferably in a range of 0.1 through 10 MPa/cm². Thus, the surface of the resulting organic ferroelectric film 4 on the side opposite to the substrate 2 can be made as an extremely smooth surface.

The method of pressing the tool 6 is not particularly limited, but various pressing machines can be used therefor. The crystallization of the low crystallinity film 4B can be promoted by heating. The method of promoting the crystallization (the method of enhancing the crystallinity) is not particularly limited, but, for example, a crystallization promotion method using a hot plate, an oven, or a vacuum oven, a crystallization promotion method using the internal heating by microwave, or a crystallization promotion method using radiant heat transmission by infrared ray can be used therefor. In particular, the crystallization promotion heat treatment process using a hot plate, an oven, a vacuum oven, and so on can preferably be used. In promoting the crystallization of the low crystallinity film 4B, by performing the promotion of the crystallization thereof to the low crystallinity film 4B in an appropriate temperature range while pressing with the tool 6, the crystallization of the organic ferroelectric material in the low crystallinity film 4B can efficiently be promoted with relative ease in a small amount of time while preventing unwanted alteration in the crystal structure of the organic ferroelectric material.

In the case of using the heat treatment as the crystallization promotion method of the low crystallinity film 4B, the process temperature is kept no lower than the crystallization temperature of the organic ferroelectric material and no higher than the melting point thereof, specifically depending on the organic ferroelectric material in use, and in the case of P(VDF/TrFE) (e.g., VDF/TrFE=75/25), the heating temperature is preferably in a range of 80 through 200° C., and further preferably in a range of 100 through 150° C. Thus, the organic ferroelectric material in the low crystallinity film 4B can efficiently be crystallized. Further, by setting the process temperature in the temperature range described above and no lower than the Curie temperature of the organic ferroelectric material, the crystallization of the organic ferroelectric material in the low crystallinity film 4B can easily and efficiently be promoted.

It should be noted here that the “process temperature” denotes the temperature of the low crystallinity film 4B, and in the heat treatment, for example, the oven or the hot plate is operated so that the low crystallinity film 4B is kept in the temperature range described above.

Further, the process time in the crystallization process is preferably in a range of 0.5 through 120 minutes, and further preferably in a range of 1 through 30 minutes depending on the organic ferroelectric material in use, the film thickness of the liquid material 4A, and so on.

Further, the low crystallinity film 4B is preferably cooled after it has been heated to enhance the crystallinity. Thus, the surface of the organic ferroelectric film 4 on the side opposite to the substrate 2 can more surely be made to have the smoothed condition. Further, the cooling is more preferably performed after the crystallinity has been enhanced and before the tool 6 is removed. In other words, it is preferable that the cooling is performed while pressing the tool 6, and after then, the tool 6 is removed. Thus, the surface of the organic ferroelectric film 4 on the side opposite to the substrate 2 can more surely be smoothed (faired).

The cooling temperature is preferably in a range of 0 through 100° C., further preferably no higher than the glass-transition temperature, and preferably no higher than a normal temperature (room temperature). Thus, the promotion of the crystallization can more surely be performed. Further, the cooling is performed at the cooling rate at which a desired crystal condition of the organic ferroelectric material can be obtained.

The method of cooling the organic ferroelectric material is not particularly limited, but, for example, a natural cooling, a method of cooling the substrate or the tool with a peltiert device, a method of providing a jacket to the tool through which refrigerant flows can preferably be cited.

Further, it is preferable that the low crystallinity film 4B is heated to be softened prior to the pressurization (fairing) with the tool 6. Thus, the surface of the organic ferroelectric film 4 on the side opposite to the substrate 2 can more surely be made to have the smoothed condition.

The material of the tool is not particularly limited, but, for example, a metal material is preferably used therefor. Further, it is preferable that a parting treatment is provided to the surface (pressing surface) of the tool 6. Thus, the removal of the tool 6 becomes easy, and the organic ferroelectric material can be prevented from adhering to the tool 6, thereby making the smoothness of the surface of the organic ferroelectric film 4 on the side opposite to the substrate 2 more excellent.

The parting treatment is not particularly limited, but a lyophobic treatment, formation of microscopic reliefs, and so on can preferably be cited.

It should be noted that in the case of using the organic ferroelectric material made of a fluorinated polymer, the adhesiveness thereof with other materials are not so high because it contains lots of fluorine, and consequently, the surface treatment of the tool 6 is not necessarily required.

In the present heating treatment step, the thermal energy excites the molecules of the organic ferroelectric material in the low crystallinity film 4B to soften the low crystallinity film 4B. Therefore, by cooling the low crystallinity film 4B while maintaining the pressed condition after promoting the phase transition to the p type to complete crystallization while adhering the tool 6 to the low crystallinity film 4B in the softened condition to pressurize the low crystallinity film 4B (pressing the tool 6 against the low crystallinity film 4B), the organic ferroelectric film 4 with the pattern formed on the tool 6 transferred thereto can be obtained.

Further, the crystallization process can be executed in the air atmosphere, but is more preferably executed in the inert atmosphere such as nitrogen or argon, or in vacuo.

The feature of the process is that the organic ferroelectric material in the low crystallinity film 4B is pressurized in the process of promoting the crystallization of the low crystallinity film 4B by heating, and consequently, the crystallization proceeds in a limited space. In other words, the crystallization of the organic ferroelectric material proceeds while maintaining the condition in which the surface of the low crystallinity film 4B on the side opposite to the substrate 2 is smoothed by the tool 6. Therefore, it can be prevented that the crystal grains of the organic ferroelectric material grow freely to make the surface coarse. Therefore, the surface of the resulting organic ferroelectric film 4 on the side opposite to the substrate 2 is smoothed, and it can be prevented that the film thickness (distance between the lower electrode 3 and the upper electrode 5) of the organic ferroelectric film 4 becomes locally small. Thus, the problem of the coarse surface caused by the crystal grains, which hinders a thinner film of P(VDF/TrFE), can be avoided, thus the lower voltage drive of the memory element 1 can be achieved.

Further, in the present embodiment, the crystallization is performed while applying an electric field between the tool 6 and the lower electrode 3.

Thus, the crystal orientations of the organic ferroelectric material in the resulting organic ferroelectric film 4, namely the polarization axes, can be aligned in a direction perpendicular to the surfaces of the lower and upper electrodes 3, 5. Therefore, in the resulting memory element 1, the polarization loss caused by the directional fluctuation of the polarization axis can be reduced, thus the polarization value of the organic ferroelectrics can fully be brought out. Further, improvement of the response of polarization reversal can be achieved, and the squareness in the hysteresis curve can be made excellent.

Further, since the voltage is applied to the low crystallinity film 4B using the lower electrode 3 and the tool 6, the voltage can easily be applied to the low crystallinity film 4B without preparing the electrodes separately.

The electric field applied to the low crystallinity film 4B by the application of the voltage is preferably no lower than the coercive field, depending on the organic ferroelectric material in use. In the case with P(VDF/TrFE), for example, it is preferably no lower than 0.3 kV/cm, and further preferably no lower than the coercive field of 0.5 MV/cm. Thus the crystal orientations of the organic ferroelectric thin film in the organic ferroelectric film 4, namely the polarization axes can be aligned in the direction perpendicular to the surfaces of the lower and the upper electrodes.

It should be noted that such application of the electric field as described above can be eliminated.

Step D: Step of Forming the Upper Electrode

Subsequently, as shown in FIG. 2G, the upper electrode 5 is formed on the low crystallinity film 4B. As described above, the surface of the organic ferroelectric film 4 on the side opposite to the lower electrode 3 is smooth, and since the upper electrode 5 is formed on such a smooth surface, the boundary face between the organic ferroelectric film 4 and the upper electrode 5 can be made extremely smooth.

The upper electrode 5 can be formed in the same manner as in the step A described above.

In a manner as described above, the memory element 1 can be manufactured.

According to such a manufacturing method, since the crystallization of the low crystallinity film 4B is performed using the tool 6, the boundary face between the low crystallinity film 4B and the upper electrode 5 can be made extremely smooth, and the low crystallinity film 4B can be crystallized in such a condition. Therefore, it becomes possible to prevent generation of the roughness of the surface caused by growth of the crystal grains, thus making the surface of the resulting organic ferroelectric film 4 extremely smooth.

As a result, even in the case in which the organic ferroelectric film 4 is made thinner, in the resulting memory element 1, the leakage current can be prevent from increasing, and the short circuit (short between the lower electrode 3 and the upper electrode 5) in the thickness direction of the organic ferroelectric film 4 can be prevented. In other words, it becomes possible to reduce the thickness of the organic ferroelectric film 4 to reduce the drive voltage.

Further, in such a manufacturing method, the memory element 1 can be formed by the process requiring relatively low temperature and using only simple equipment. Therefore, the cost reduction of the manufacturing equipment can be achieved, and the range of choices for the material composing the memory element 1, consequently the memory device, is expanded. For example, by using a resin material for the substrate 2, the memory element 1 or the memory device with flexibility can be manufactured.

### Second Example

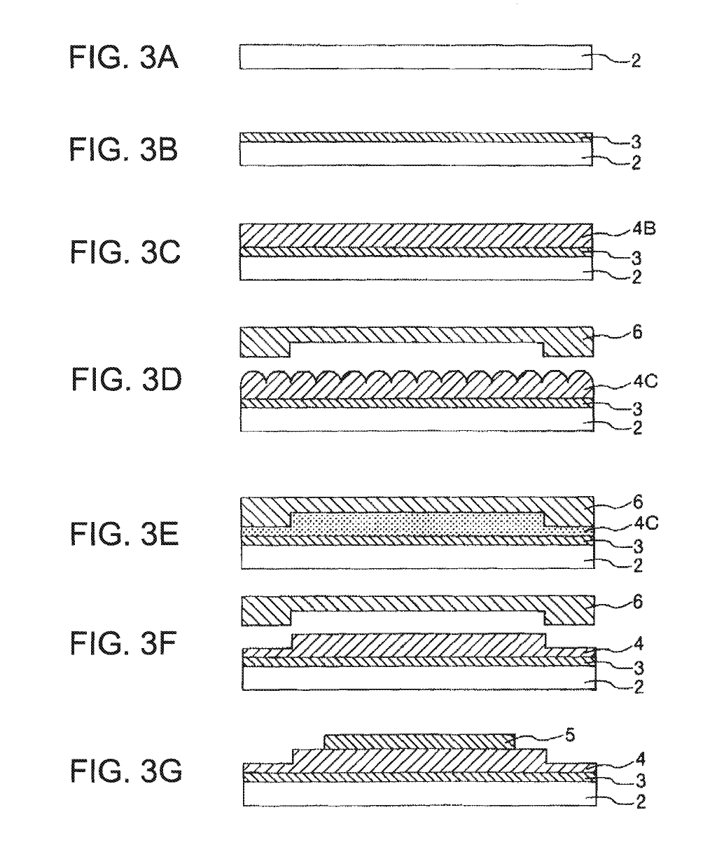

Then, a second example of the manufacturing method of the memory element 1 will be explained with reference to FIGS. 3A through 3G. It should be noted that hereinafter explanations will be presented focusing on items different from the first example described above, and explanations for the same items will be omitted.

The manufacturing method of the memory element 1 in the second example is the same as the manufacturing method of the memory element 1 in the first example described above except the fact that in the step (b) the tool 6 is pressed against the low crystallinity film 4B, which is in a softened state, to form the organic ferroelectric film 4 after the low crystallinity film 4B has been crystallized.

Specifically, the manufacturing method of the memory element 1 in the second example includes a step of forming the lower electrode 3 (step A), a step of applying a liquid material containing the organic ferroelectric material on the lower electrode 3, then drying the material to form a low crystallinity film (step (a)) (step B), a step of heating and pressurizing the low crystallinity film to form the organic ferroelectric film after the crystallization of the low crystallinity film has been promoted (step (b)) (step C), and a step of forming the upper electrode on the organic ferroelectric film (step D).

The step A, step B, and step D in the manufacturing method of the memory element 1 in the second example are the same as the step A, step B, and step D, respectively, according to the first example.

In the step C according to the second example, when promoting the crystallization of the organic ferroelectric material in the low crystallinity film 4B to form the organic ferroelectric film 4, the low crystallinity film 4B is heated to enhance the crystallinity to form a crystalline film 4C as shown in FIG. 3D, then in the condition in which the crystalline film 4C is heated to be softened, the tool 6 is pressed against the substrate 2 via the crystalline film 40 as shown in FIG. 3E, and after then the tool 6 is removed to obtain the organic ferroelectric film 4.

The heating temperature (process temperature) for softening is not particularly limited, but is preferably in a range of 80 through 200° C. Thus, the surface of the resulting organic ferroelectric film 4 on the side opposite to the substrate 2 can be made extremely smooth.

Further, it is possible that when pressing the softened crystalline film 4C with the tool 6, the voltage is applied between the tool 6 and the substrate 2 (or the lower electrode 3), as in the case with the first example described above, thereby aligning the directions of the polarized axes of the ferroelectric material in the crystalline film 4C.

In addition, as the conditions such as tool 6, pressing, a heat treatment, and cooling, the same conditions as described in the first example can be used.

According to such a manufacturing method, even if the roughness caused by the crystal grains of the organic ferroelectric material is formed on the surface of the crystalline film 4C on the side opposite to the substrate 2 by the crystallization, the surface of the organic ferroelectric film 4 on the side opposite to the substrate 2 can be made smooth. Therefore, the film thickness of the organic ferroelectric film 4 can be prevented from locally decreasing. As a result, even in the case in which the organic ferroelectric film 4 is made thinner, in the resulting memory element 1, the leakage current can be prevent from increasing, and the short circuit in the thickness direction of the organic ferroelectric film 4 can be prevented. In other words, it becomes possible to reduce the thickness of the organic ferroelectric film 4 to reduce the drive voltage.

Also in a manner as described above, the memory element 1 can be manufactured.

It should be noted that in the second example, instead of performing pressing with the tool as described above before forming the upper electrode 5, it is possible that the upper electrode 5 is formed first on the low crystallinity film 4B, and then the tool 6 is pressed against the substrate 2 via the upper electrode 5 and the low crystallinity film 4B.

Memory Device

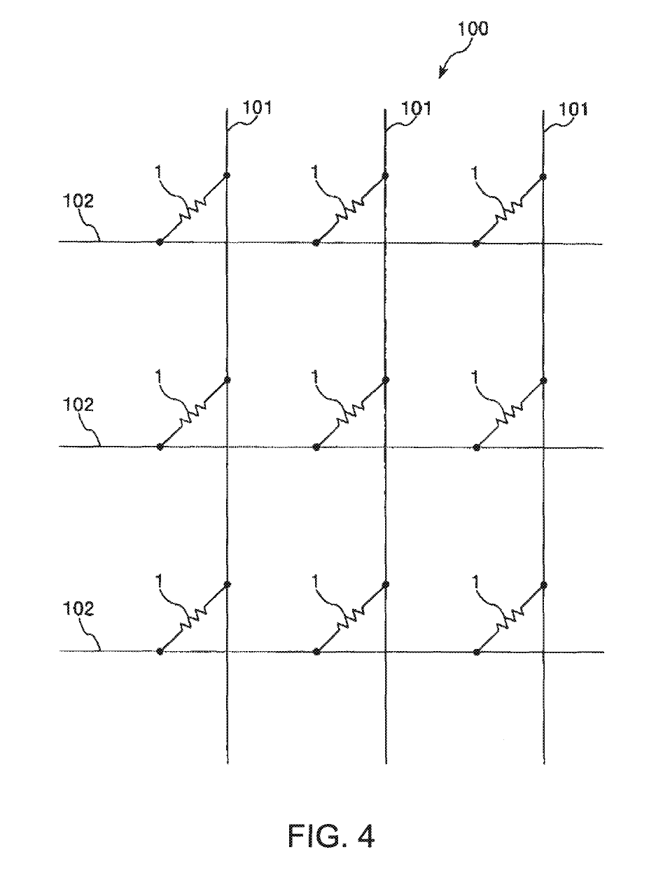

Now, as an example of the memory device according to the invention, a CP type memory device using the memory element 1 of the embodiment of the invention will be explained with reference to FIG. 4.

FIG. 4 is a diagram schematically showing a circuit configuration of the memory device (a memory array) using the memory element 1 according to the embodiment of the invention.

The memory device 100 shown in FIG. 4 is a memory device having a memory array composed of a plurality of CP type memory cells.

Further specifically, the memory device 100 has the memory array composed of first signal electrodes 101 for row election and second signal electrodes 102 for column selection arranged perpendicular to each other.

One of the first electrode 101 and the second electrode 102 is a word line and the other thereof is a bit line, and each of the intersections between them forms the memory element 1 according to the embodiment of the invention. It should be noted that in FIG. 4 the memory element 1 is schematically illustrated as a resistor connected to the lines in the vicinity of each intersection.

In such a memory device 100, even if the organic ferroelectric material having a crystalline property is used as the composing material of the organic ferroelectric film 4, reduction of the drive voltage can be achieved. Further, such a memory device 100 has a superior reliability because of the reduction of the leakage current and prevention of the short circuit.

### Second Embodiment

A second embodiment of the invention will hereinafter be described. It should be noted that regarding the second embodiment, explanations for the same items as those in the first embodiment described above will be omitted.

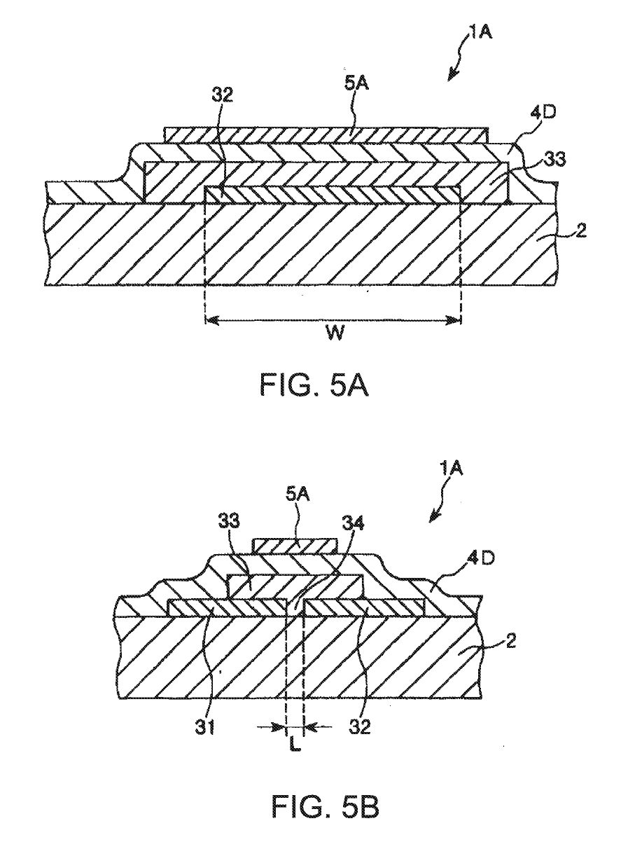

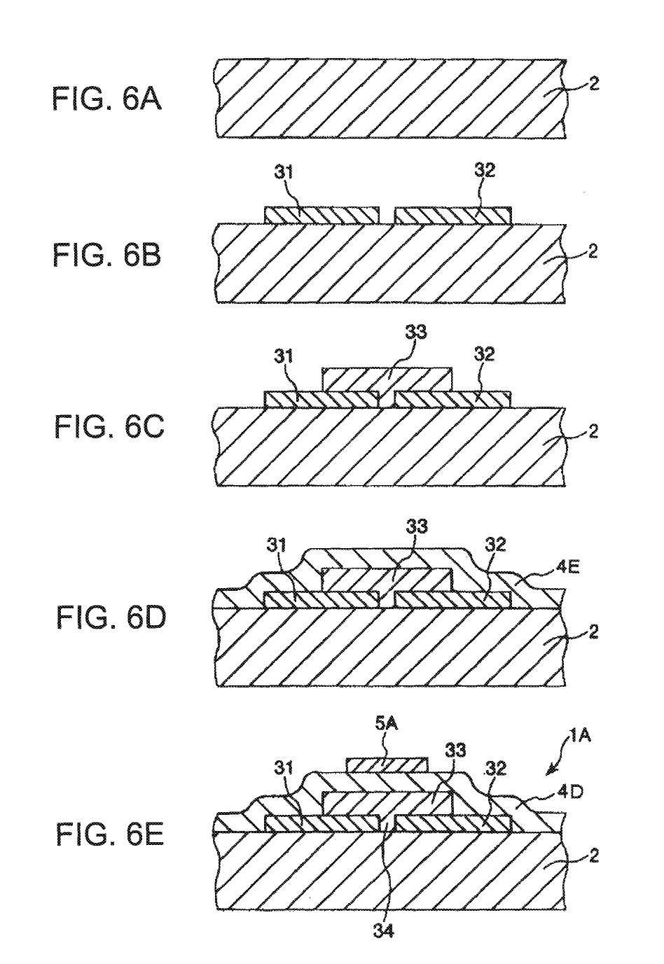

FIG. 5 is a cross-sectional view showing an embodiment of the memory element according to the second embodiment of the invention. It should be noted that FIG. 5A shows a vertical cross-sectional view of the memory element, and FIG. 5B shows a horizontal cross-sectional view thereof. Further, it should be noted that for the sake of explanatory convenience, “the upper side” and “the lower side” in FIGS. 6A and 6B are hereinafter referred to as “the upper side” and the “lower side,” respectively.

The memory element 1A shown in FIGS. 5A and 5B has a configuration of a one transistor (so-called 1T type) memory element.

The memory element 1A includes a source region 31 and a drain region 32 formed on the substrate 2 with a distance therebetween, a semiconductor film 33 provided between the source region 31 and the drain region 32 and having a contact with each of them, an organic ferroelectric film (a recording film) 4D formed so as to cover the semiconductor film 33, and a gate electrode 5A formed on the organic ferroelectric film 4D.

In such a memory element 1A, a voltage is applied between the gate electrode 5A and both of the source region 31 and the drain region 32 to change the polarization state in the organic ferroelectric film 4D, thereby performing recording (writing) of data. Further, such a polarization state is maintained even after application of the electric field is stopped, and by detecting the current flowing between the source region 31 and the drain region 32, reproduction (reading) of the record can be performed. Therefore, the memory element 1A can be used for a nonvolatile memory.

In the memory element 1A, as shown in FIG. 5B, a region between the source region 31 and the drain region 32 of the semiconductor film 33 serves as a channel region 34 in which carriers are transported. Here, in the channel region 34, the length in the carrier transport direction, namely the distance between the source region 31 and the drain region 32 is defined as a channel length L, and the length in the direction perpendicular to the channel length L direction is defined as a channel width W.

Such a memory element 1A has a structure in which the source region 31 and the drain region 32 are disposed on the substrate 2 side of the gate electrode 5A via the organic ferroelectric film 4D, namely the top-gate structure.

Then, the manufacturing method of the memory element according to the invention will be explained with reference to FIGS. 6A through 6E using the manufacturing method of the memory element 1A as one example.

FIGS. 6A through 6E are diagrams for explaining the manufacturing method of the memory element shown in FIGS. 5A and 5B.

Regarding the manufacturing of the organic ferroelectric film 4D, the manufacturing method of the memory element 1A is the same as the manufacturing method of the memory element 1 according to the first embodiment (the first or second example) described above.

Specifically, the manufacturing method of the memory element 1A includes a step of forming the source region 31, the drain region 32, and the semiconductor film 33 (step A), a step of applying a liquid material containing the organic ferroelectric material on the semiconductor film 33 (the channel region 34), then drying the material to form a low crystallinity film (step (a)) (step B), a step of crystallizing the low crystallinity film to form (using a tool) the organic ferroelectric film (step (b)) (step C), and a step of forming the gate electrode 5A on the organic ferroelectric film (step D).

Step A: Step of forming the source region 31, drain region 32, and the semiconductor film 33

Firstly, as shown in FIG. 6A, a substrate 2 such as a semiconductor substrate, a glass substrate, or a resin substrate is prepared, and on the upper surface of the substrate 2, the source region 31 and the drain region 32 are formed as shown in FIG. 6B, and after then, the semiconductor film 33 is formed as shown in FIG. 6C.

The forming methods of the source region 31, drain region 32, and the semiconductor film 33 are each not particularly limited, and the same method as in the case with the lower electrode 3 can be used.

Further, the composing material of the semiconductor film is not particularly limited, and various organic semiconductor materials and various inorganic semiconductor materials can be used, but, in view of making a flexible device, the organic semiconductors are preferably used.

As the organic semiconductor material, for example, small molecule organic semiconductor materials such as naphthalene, anthracene, tetracene, pentacene, hexacene, phthalocyanine, perylene, hydrazone, triphenylmethane, diphenylmethane, stilbene, arylvinyl, pyrazoline, triphenylamine, triarylamine, oligothiophene, phthalocyanine, or derivatives of the above, or polymeric semiconductor materials such as poly-N-vinylcarbazole, polyvinylpyrene, polyvinyl anthracene, polythiophene, polyalkylthiophene, polyhexylthiophene, poly(p-phenylenevinylene), polythenylenevinylene, polyarylamine, pyrene-formaldehyde resin, ethylcarbazole-formaldehyde resin, fluorene-bithiophene copolymer, fluorene-arylamine copolymer, or derivatives of the above can be cited, and these materials can be used alone or in combination, and in particular, materials made mainly of polymeric organic semiconductor materials (conjugated polymeric materials) are preferably be used. The conjugated polymeric materials have particularly high carrier migratory aptitude because of characteristic distributions of the electron clouds.

Further, in these materials, materials made mainly of at least one of fluorene-bithiophen copolymer, fluorene arylamine copolymer, polyarylamine, or derivatives of the above are preferably used as polymeric organic semiconductor materials (conjugated polymeric materials) for the reasons of the oxidation resistance and the stability in the air.

By composing the semiconductor film 33 using such a polymeric organic semiconductor material as the principal material, a thinner and more lightweight device can be realized, and further a memory device superior in flexibility can be achieved, it is suitable for application as a nonvolatile memory to be implemented in various flexible electronic devices represented by a flexible display and so on.

The thickness of the semiconductor film 33 (the organic semiconductor material) is preferably in a range of about 1 through 500 nm, and further preferably in a range of about 10 through 200 nm.

Step B: Step of Forming a Low Crystallinity Film (the Step (a))

Subsequently, a liquid material containing the crystalline organic ferroelectric material is applied (forming a film of the liquid material) so as to cover the semiconductor film 33, and then dried to form the low crystallinity film (including an amorphous film) 4E as an intermediate product for forming the organic ferroelectric film 4D as shown in FIG. 6D.

The formation of the low crystallinity film 4E can be performed in the same manner as the formation of the low crystallinity film 4B of the first example described above.

Even if the unevenness caused by the source region 31, the drain region 32, and the semiconductor film 33 is formed as in the present embodiment, by forming the low crystallinity film 4E using a liquid source misted chemical deposition method (LSMCD method), equalization of the thickness of the resulting low crystallinity film 4E can easily be achieved. This is caused by the fact that the particle size of the droplet formed by the liquid source misted chemical deposition method (LSMCD method) is small.

Step C: Step of Forming the Organic Ferroelectric Film 4D (the Step (b))

Subsequently, as shown in FIG. 6E, the crystallization of the low crystallinity film 4E is promoted to form the organic ferroelectric film 4D.

The formation (crystallization) of the organic ferroelectric film 4D can be performed in the same manner as the formation of the organic ferroelectric film 4 of the first embodiment (the first or second example) described above. Specifically, the surface of the organic ferroelectric film 4D on the side opposite to the substrate 2 can be smoothed using the tool.

Step D: Step of Forming the Gate Electrode

Subsequently, as shown in FIG. 6E, the gate electrode 5A is formed on the organic ferroelectric film 4.

The gate electrode 5 can be formed in the same manner as in the step A described above.

In a manner as described above, the memory element 1A can be manufactured.

By the manufacturing method as explained hereinabove, the memory element 1A with superior response and hysteresis characteristic can be manufactured.

In particular, in the present embodiment, prior to the step of forming the low crystallinity film 4E, the source region 31 and the drain region 32 are formed on the substrate 2, the channel region 34 (the semiconductor film 33) is formed, the low crystallinity film 4E is formed on the channel region 34 in the step of forming the low crystallinity film 4E, and the gate electrode 5A is formed on the organic ferroelectric film 4D after the step of forming the organic ferroelectric film 4D. Thus, the memory element 1A which can be used for the so-called 1T (transistor) memory device can be obtained.

Memory Device

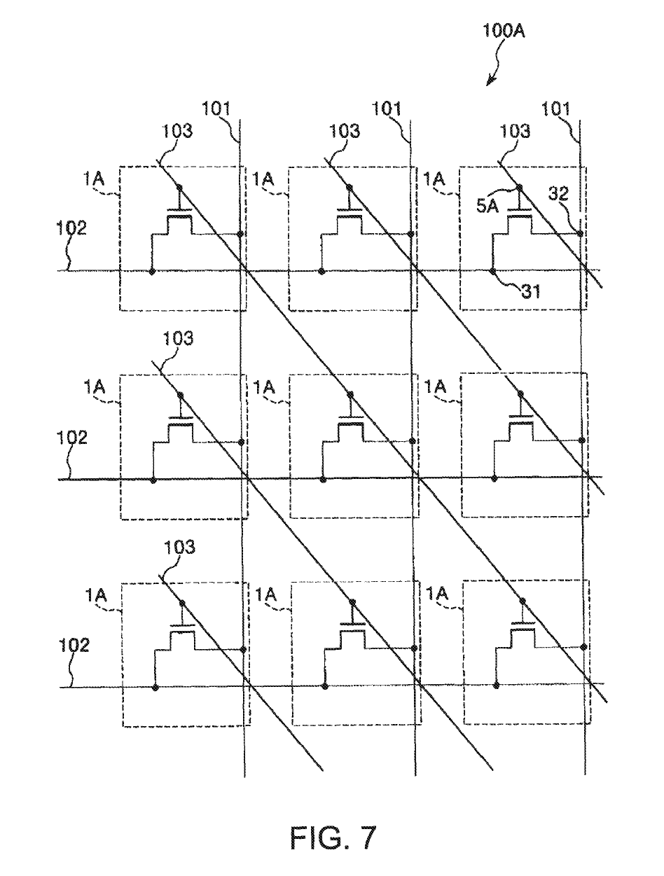

Now, as another example of the memory device according to the invention, a memory device using the memory element 1A of the embodiment of the invention will be explained with reference to FIG. 7.

A memory device 100A shown in FIG. 7 is a so-called 1T memory device.

Further specifically, the memory device 100A has a memory array formed by arranging first signal electrodes 101 for row selection and second signal electrodes 102 for column selection perpendicular to each other, and third signal electrodes 103 passing through in the vicinity of each of the intersections between the first signal electrodes 101 and the second signal electrodes 102, and connecting the memory element 1A to each of the intersections.

One of the first signal electrode 101 and the second signal electrode 102 serves as a word line, and the other thereof serves as a bit line. Further, in the vicinity of each of the intersections between the first signal electrodes 101 and the second signal electrodes 102, the first signal electrode 101 is connected to the drain region 32, and the second signal electrode 102 is connected to the source region 31. The third signal electrode 103 is connected to the gate electrode 5A, and functions as a write line for writing data.

Such a memory device 1000A is capable of nondestructive readout.

It should be noted that although 2T2C, or further, 1T1C memory devices are preferable from the viewpoint of a stable operation of the memory device (the memory element), from the viewpoint of capability of nondestructive readout (NDRO), 1T memory device is preferable.

It should be noted that although what is related to the memory element according to the invention is explained in the present embodiment, the memory element and the manufacturing method thereof according to the invention can also be applied to a transistor such as a thin film transistor and the manufacturing method thereof. In other words, the transistors can be manufactured in the same manner as the manufacturing method according to the present embodiment. In this case, reduction of the drive voltage of the transistor can be achieved, and the response of the transistor can be improved.

Further, in manufacturing the 1T1C memory device or the 2T2C memory device, the transistor part of the memory array can be manufactured in the same manner as the manufacturing method of the memory element according to the present embodiment. Thus, the characteristics of the memory device can be improved. On this occasion, by manufacturing the capacitor part of the memory array using the manufacturing method of the memory device according to the first embodiment described above, the characteristics of the memory device can further be improved.

The memory devices 100, 100A as described hereinabove can be applied to various electronic apparatuses. Thus, there can be provided an electronic apparatus capable of achieving the reduction of the drive voltage even if the organic ferroelectric material with a crystalline property is used as the composing material of the organic ferroelectric film 4. Further, such an electronic apparatus has a superior reliability because of the reduction of the leakage current and the prevention of the short circuit.

As the electronic apparatus, for example, a personal computer, a portable information apparatus can be cited.

Although the invention is explained hereinabove based on the illustrated embodiments, the invention is not limited to these embodiments.

For example, each of the sections composing the embodiments of the invention can be replaced with anything with a similar function, or added with other configurations.

Further, for example, one or more layers with any purpose can be provided between the organic ferroelectric film 4 and the lower electrode 3 and/or between the organic ferroelectric film 4 and the upper electrode 4. Further, one or more layers with any purpose can be provided between the organic ferroelectric film 4D and the semiconductor film 33.

Further, the transistor in each of the 2T2C, 1T1C, CP, and 1T memory devices as described above can have a configuration such as a single crystal Si transistor, an amorphous silicon thin film transistor (a-Si TFT), a Tow-temperature polysilicon thin film transistor (LTPS TFT), a high-temperature polysilicon thin film transistor (HTPS), or an organic thin film transistor (organic TFT).

### Specific Examples

Specific examples according to the invention will hereinafter be described.

### Specific Example 1

The memory element as shown in FIG. 1 was manufactured as described below by the manufacturing method according to the invention.

Specifically, a substrate with average thickness of 300 μm made of polyimide was firstly prepared.

Then, the lower electrode of 100 nm thick made of Al was formed on the substrate using an evaporation method.

Subsequently, the liquid material of the following composition was applied by a spin coat method, and dried at 80° C. for 20 minutes to obtain the low crystallinity film.

### Composition of the Liquid Material

### P(VDF/TrFE) [VDF/TrFE=75/25]: 3 wt %

Methyl ethyl ketone:2-butanone (MEK): 97 wt %

### Curie point (Tc): Approx. 80° C.

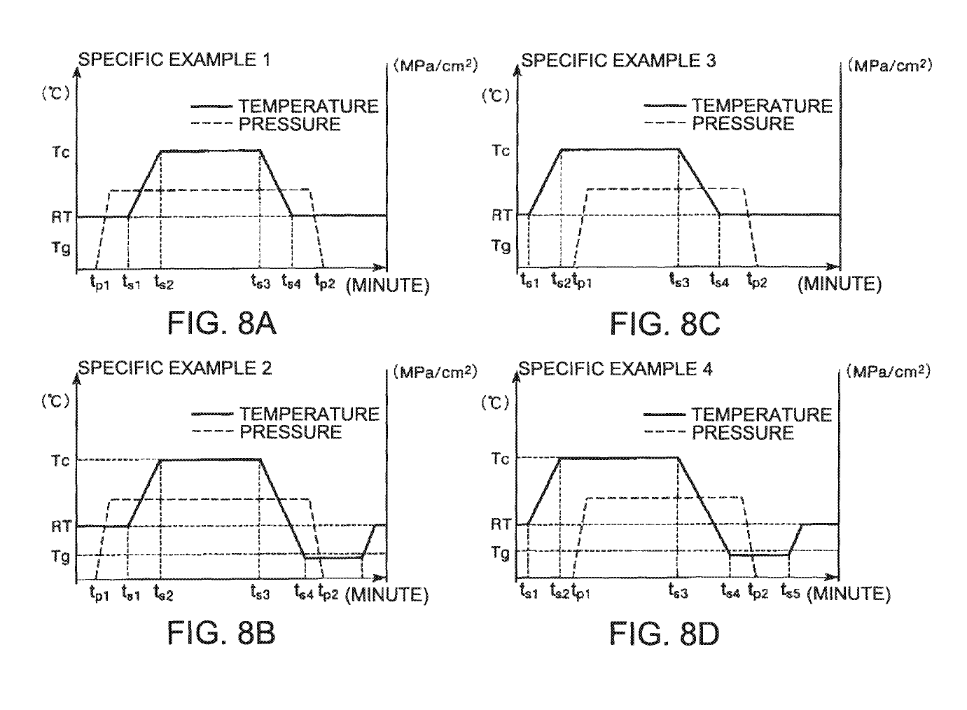

Subsequently, as shown in FIG. 8A, the tool previously surface-treated with PTFE was pressed against the low crystallinity film at a pressure of 5 MPa/cm², and the heating process was executed at 140° C. (no lower than the Curie point (Tc) in the Tₛ₂-Tₛ₃ period shown in FIG. 8A) for 15 minutes (in the Tₛ₁-Tₛ₄ period). FIGS. 8A through 8D are each a diagram for explaining a relationship between time and the temperature of the tool and the substrate, and a relationship between time and the pressure of the tool.

Subsequently, after the natural cooling to the room temperature (normal temperature (RT): 25° C.), the tool was separated to obtain the organic ferroelectric film of 50 nm thick.

Then, the surface of the organic ferroelectric film separated from the tool was observed with a microscope, and the surface condition was evaluated according to the following criteria of four levels. The evaluation result is shown in Table 1.

### A: The roughness caused by crystal grains was hardly observed.

### B: The roughness caused by crystal grains was observed, and the concave was very shallow.

### C: The roughness caused by crystal grains was observed, and the concave was deep.

### D: The roughness caused by crystal grains caused pinholes in the organic ferroelectric film.

[Table 1]

TABLE 1

| | | | | Surface |
|---|---|---|---|---|
| | Heating | | | condition of |
| | temperature | | | the |
| | (pressurized) | Cooling rate | Pressure | ferroelectric |
| | (° C.) | (° C./min) | (MPa/cm²) | film |
| Specific | 140 | 1 | 5 | B |
| Example 1 | | | | |
| Specific | 140 | 10 | 5 | A |
| Example 2 | | | | |
| Specific | 140 | 1 | 8 | A |
| Example 3 | | | | |
| Specific | 140 | 10 | 8 | A |
| Example 4 | | | | |
| Specific | 70 | 10 | 11 | A |
| Example 5 | | | | |
| Specific | 90 | 10 | 9 | A |
| Example 6 | | | | |
| Specific | 190 | 10 | 0.2 | B |
| Example 7 | | | | |
| Specific | 210 | 10 | 0.05 | B |
| Example 8 | | | | |
| Specific | 140 | 10 | 2 | B |
| Example 9 | | | | |
| Specific | 160 | 10 | 1 | B |
| Example 10 | | | | |
| Comparative | 140 | 10 | — | D |
| Example | | | | |

Then, the upper electrode of 10 nm thick made of Al was formed thereon using an evaporation method.

### Specific Example 2

The memory element was manufactured in the same manner as in the specific example 1 except the fact that the low crystallinity film treated with the heating process to promote crystallization was thereafter quick-cooled (10° C./min or more) to below the Curie point as shown in FIG. 8B.

Further, the surface of the organic ferroelectric film separated from the tool was observed with a microscope, and the surface condition was evaluated according to the following criteria of four levels. The evaluation result is shown in Table 1.

### Specific Example 3

The memory element as shown in FIG. 1 was manufactured as described below by the manufacturing method according to the invention.

More specifically, a substrate with average thickness of 300 μm made of polyimide was firstly prepared.

Then, the lower electrode of 100 nm thick made of Al was formed on the substrate using an evaporation method.

Subsequently, the liquid material of the following composition was applied by a spin coat method, and then heated to 140° C. (no lower than the Curie point (Tc)) to promote the crystallization of the liquid material, thereby obtaining the crystalline film.

### Composition of the Liquid Material

### P(VDF/TrFE) [VDF/TrFE=75/25]: 3 wt %

Methyl ethyl ketone:2-butanone (MEK): 97 wt %

### Curie point (Tc): Approx. 80° C.

Then, the tool previously surface-treated with PTFE was pressed at a pressure of 8 MPa/cm² for 20 minutes.

Subsequently, after cooling to the room temperature (normal temperature (RT): 25° C.), the tool was separated to form the organic ferroelectric film of 50 nm thick.

Then, the surface of the organic ferroelectric film separated from the tool was observed with a microscope, and the surface condition was evaluated according to the following criteria of four levels. The evaluation result is shown in Table 1.

Then, the upper electrode of 100 mm thick made of Al was formed thereon using an evaporation method.

### Specific Example 4

The same operation as in the specific example 3 was executed except the fact that the quick cooling (10° C./min or more) was executed after the tool was pressed against the crystalline film, thereby obtaining the organic ferroelectric film with a smooth surface.

Further, the surface of the organic ferroelectric film separated from the tool was observed with a microscope, and the surface condition was evaluated according to the following criteria of four levels. The evaluation result is shown in Table 1.

### Specific Examples 5 through 10

The organic ferroelectric films were formed in the same manner as in the specific example 1 described above except the fact that the pressure and the process temperature were set as shown in Table 1.

### Comparative Example

The memory element was manufactured in the same manner as in the specific example 1 described above except the fact that the pressing with the tool was eliminated.

As shown in Table 1, in either of the specific examples 1 through 10, the surface of the organic ferroelectric film on the side opposite to the substrate was smooth. In comparison therewith, in the comparative example, there was observed a noticeable roughness caused by crystal grains on the surface of the organic ferroelectric film on the side opposite to the substrate.

Further, the memory elements according to the specific examples 1 through 10 could be driven with a low voltage (approx. 2V). In contrast, the memory element in the comparative example could not be driven. Conceivably, this was caused by increase in leakage current or short circuit.

What is claimed is:

1. A method of forming an organic ferroelectric film configured to include an organic ferroelectric material with a crystalline property as a principal material, comprising:
(a) forming a low crystallinity film having a crystallinity lower than a crystallinity of the organic ferroelectric film on one surface of a substrate; and
(b) forming the organic ferroelectric film from the low crystallinity film,
wherein the step (a) includes applying a liquid material containing the organic ferroelectric material on the one surface of the substrate and then drying the liquid material, and
the step (b) includes heating and pressurizing the low crystallinity film to enhancing the crystallinity in the low crystallinity film while fairing the low crystallinity film.

2. The method of forming an organic ferroelectric film according to claim 1,
wherein the crystallinity in the low crystallinity film is no higher than 80% of the crystallinity of the organic ferroelectric film.

3. The method of forming an organic ferroelectric film according to claim 1,
wherein in the step (b), the pressure in the pressurizing is in a range of 0.1 through 10 MPa/cm².

4. The method of forming an organic ferroelectric film according to claim 1,
wherein a thickness of the organic ferroelectric film is in a range of 5 through 500 nm.

5. The method of forming an organic ferroelectric film according to claim 1,
wherein the organic ferroelectric material is mainly composed of one of a copolymer of vinylidene fluoride and trifluoroethylene, a polymer of vinylidene fluoride, and a combination of the copolymer of vinylidene fluoride and trifluoroethylene and the polymer of vinylidene fluoride.

6. The method of forming an organic ferroelectric film according to claim 1,
wherein the liquid material containing the organic ferroelectric material is a solution dissolving the organic ferroelectric material with a solvent.

7. The method of forming an organic ferroelectric film according to claim 1,
wherein in the step (b), the temperature in the heating for enhancing the crystallinity is in a range of 80 through 200° C.

8. The method of forming an organic ferroelectric film according to claim 1,
wherein the step (b) includes performing cooling while maintaining the pressurized state after the crystallinity has been enhanced.

9. The method of forming an organic ferroelectric film according to claim 8,
wherein the cooling is performed at a temperature no higher than the glass-transition temperature of the organic ferroelectric material.

10. The method of forming an organic ferroelectric film according to claim 1, further comprising:
(c) heating to soften the low crystallinity film,
wherein the step (c) is executed after the step (a) and prior to the step (b).

11. The method of forming an organic ferroelectric film according to claim 1,
wherein in the step (b), the fairing is executed by pressing a tool capable of defining an effective area of the organic ferroelectric film against the substrate.

12. The method of forming an organic ferroelectric film according to claim 11,
wherein the tool is provided with a parting treatment on a pressing surface.

13. The method of forming an organic ferroelectric film according to claim 11, further comprising:
(d) forming a first electrode on the substrate,
wherein the step (d) is executed prior to the step (a),
in the step (a), the low crystallinity film is formed on the surface of the first electrode on a side opposite to the substrate, and
in the step (b), in the pressurizing, the crystallization is performed while applying an electric field between the tool and the first electrode.

14. A method of manufacturing an organic ferroelectric film configured to include an organic ferroelectric material with a crystalline property as a principal material, comprising:
(a) forming a low crystallinity film having a crystallinity lower than a crystallinity of the organic ferroelectric film on one surface of a substrate; and
(b) forming the organic ferroelectric film from the low crystallinity film,
wherein the step (a) includes applying a liquid material containing the organic ferroelectric material on the one surface of the substrate and then drying the liquid material, and
the step (b) includes:
(e) heating the low crystallinity film to form a crystalline film from the low crystallinity film enhanced in the crystallinity, and
(f) heating and pressurizing the crystalline film to fair the crystalline film, thereby forming the organic ferroelectric film.

15. A method of manufacturing a memory element using an organic ferroelectric film configured to include an organic ferroelectric material with a crystalline property as a principal material, comprising:
(d) forming a first electrode on one surface of a substrate;
(a) forming a low crystallinity film having a crystallinity lower than a crystallinity of the organic ferroelectric film on a surface of the first electrode on a side opposite to the substrate;
(b) forming the organic ferroelectric film from the low crystallinity film, and
(g) forming a second electrode on a surface of the organic ferroelectric film on a side opposite to the first electrode,
wherein the step (a) includes applying a liquid material containing the organic ferroelectric material on the one surface of the substrate and then drying the liquid material, and
the step (b) includes heating and pressurizing the low crystallinity film to enhancing the crystallinity in the low crystallinity film while fairing the low crystallinity film.

16. The method of manufacturing a memory element according to claim 15, further comprising:
(h) forming a semiconductor film,
wherein the step (h) is executed after the step (d) and prior to the step (a),
the first electrode formed in the step (d) includes a pair of electrodes distant from each other,
in the step (h), the semiconductor film is formed so as to have contact with each of the pair of electrode, and
in the step (a), the low crystallinity film is formed on the surface of the semiconductor film on a side opposite to the substrate.

17. A memory device, comprising:
the memory element manufactured by the method of manufacturing a memory element according to claim 15.

18. An electronic apparatus, comprising:
the memory device according to claim 17.
